(19) United States
(12) Patent Application Publication
(10) Pub. No.: US 2013/0278546 A1
(43) Pub. Date: Oct. 24, 2013

(54) TOUCH PANEL

(71) Applicants: Hyun Jun KIM, Gyunggi-do (KR); Ho Joon PARK, Gyunggi-do (KR)

(72) Inventors: Hyun Jun KIM, Gyunggi-do (KR); Ho Joon PARK, Gyunggi-do (KR)

(73) Assignee: SAMSUNG ELECTRO-MECHANICS CO., LTD., Gyunggi-do (KR)

(21) Appl. No.: 13/549,222

(22) Filed: Jul. 13, 2012

(30) Foreign Application Priority Data
Apr. 24, 2012 (KR) 10-2012-0042816

(51) Int. Cl. H03K 17/975; G06F 3/044

(52) U.S. Cl. 345/174; 200/600

(57) ABSTRACT

Disclosed herein is a touch panel, including: a transparent substrate; a first electrode pattern formed on the transparent substrate in a mesh pattern; an insulating layer formed on the transparent substrate; and a second electrode pattern formed on an exposed surface of the insulating layer and having an intersecting area facing the first electrode pattern formed in a mesh pattern and an area other than the intersecting area formed in a surface type. By this configuration, even though the thickness of the insulating layer is thinly manufactured, it is possible to secure the desired touch sensitivity and effectively shield noises occurring from an image display device.

### CROSS REFERENCE TO RELATED APPLICATION

This application claims the benefit of Korean Patent Application No. 10-2012-0042816, filed on Apr. 24, 2012, entitled “Touch Panel”, which is hereby incorporated by reference in its entirety into this application.

### BACKGROUND OF THE INVENTION

1. Technical Field

The present invention relates to a touch panel.

2. Description of the Related Art

In accordance with the growth of computers using a digital technology, devices assisting computers have also been developed, and personal computers, portable transmitters and other personal information processors execute processing of text and graphics using a variety of input devices such as a keyboard and a mouse.

While the rapid advancement of an information-oriented society has widened the use of computers more and more, it is difficult to efficiently operate products using only a keyboard and a mouse currently serving as an input device. Therefore, the necessity for a device that is simple, has minimum malfunction, and is capable of easily inputting information has increased. Therefore, the necessity for a device that is simple, has minimum malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

This touch panel is mounted on a display surface of an image display device such as an electronic organizer, a flat panel display device including a liquid crystal display (LCD) device, a plasma display panel (PDP), an electroluminescence (El) element, or the like, and a cathode ray tube (CRT) to thereby be used to allow users to select desired information while viewing the image display device.

In addition, the touch panel is classified into a resistive type touch panel, a capacitive type touch panel, an electromagnetic type touch panel, a surface acoustic wave (SAW) type touch panel, and an infrared type touch panel. These various types of touch panels are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch panel and the capacitive type touch panel have been prominently used in a wide range of fields.

In the touch panel according to the prior art, the sensing electrode is formed as indium tin oxide (ITO). However, the ITO has excellent electric conductivity, but since indium that is a raw material is expensive rare earth metal and is expected to be depleted within about 10 years, cannot be smoothly supplied.

For this reason, as in the touch panel described in Korean Patent Laid-Open Publication No. 10-2010-0091497, researches for forming electrodes using metals have been actively progressed. There is an advantage in that the electrodes of metals can be smoothly supplied while having excellent electric conductivity. However, there is problem in that the electrodes of metals may be visually seen by users due to opacity of metals. For this reason, the electrodes are formed to have a width in a unit of μm and in a mesh structure. As such, the touch panel according to the prior art may degrade performance of shielding noises occurring in an image display device.

Recently, for simplification and thinness of a touch panel structure, a touch panel structure in which electrode patterns are directly formed on one surface of window glass has been proposed. An example thereof may include a structure of the touch panel referred to as a G2 structure.

A detailed example of the disclosed G2 structure may include a structure (SITO type) in which an ITO single layer is formed on a window using a bridge. However, the structure is vulnerable to noises from the image display device due to the sensing electrode directly facing the image display device and therefore, there is a need to use the front electrode layer for shielding noises or has been restrictedly used for the image display device in which an extremely small amount of noise occurs.

Meanwhile, the ITO dual layer type has a structure in which ITO patterns (Bar & stripe patterns) of two layers, having an insulating layer formed therebetween, are formed on one surface of the window. The foregoing structure has excellent performance of shielding noises from the image display device by covering the sensing electrode (stripe) with a wide driving electrode (bar). However, the dual layer type needs an insulating layer of approximately 100 μm or more so as to secure appropriate capacitance (C) and touch strength (delta C) that can be controlled by a touch IC and therefore, cannot be thinned. It is impossible to implement the insulating layer having the foregoing thickness only by the current G2 process.

### SUMMARY OF THE INVENTION

The present invention has been made in an effort to provide a touch panel capable of being manufactured to minimize a thickness of members, such as an insulating layer formed between electrode patterns facing each other, and the like, and effectively shielding noises occurring from an image display device, by providing a structure in which capacitance is not excessively largely formed while an electrode pattern has low resistance.

According to a first preferred embodiment of the present invention, there is provided a touch panel, including: a transparent substrate; a first electrode pattern formed on the transparent substrate in a mesh pattern; an insulating layer formed on the transparent substrate; and a second electrode pattern formed on an exposed surface of the insulating layer and having an intersecting area facing the first electrode pattern formed in a mesh pattern and an area other than the intersecting area formed in a surface type.

The touch panel may further include: an image display device formed in an exposed surface direction of the insulating layer.

At least one of the first electrode pattern and the second electrode pattern formed in the intersecting area may be formed of any one selected from copper (Cu), aluminum (Al), gold (Au), silver (Ag), titanium (Ti), palladium (Pd), and chromium (Cr), or a combination thereof.

At least one of the first electrode pattern and the second electrode pattern formed in the intersecting area may be formed of metal silver formed by exposing/developing a silver salt emulsion layer.

The second electrode pattern formed in the area other than the intersecting area may be formed of poly-3,4-ethylenedioxythiophene/polystyrenesulfonate (PEDOT/PSS), polyaniline, polyacetylene, or polyphenylenevinylene.

The second electrode pattern formed in the area other than the intersecting area may be formed of indium-tin oxide.

According to a second preferred embodiment of the present invention, there is provided a touch panel, including: a transparent substrate; a first electrode pattern formed on one surface of the transparent substrate in a mesh pattern; and a second electrode pattern formed on the other surface of the transparent substrate and having an intersecting area facing the first electrode pattern formed in the mesh pattern and an area other than the intersecting area formed in a surface type.

The touch panel may further include: an image display device formed in the other surface direction of the transparent substrate.

At least one of the first electrode pattern and the second electrode pattern formed in the intersecting area may be formed of any one selected from copper (Cu), aluminum (Al), gold (Au), silver (Ag), titanium (Ti), palladium (Pd), and chromium (Cr), or a combination thereof.

At least one of the first electrode pattern and the second electrode pattern formed in the intersecting area may be formed of metal silver formed by exposing/developing a silver salt emulsion layer.

The second electrode pattern formed in the area other than the intersecting area may be formed of poly-3,4-ethylenedioxythiophene/polystyrenesulfonate (PEDOT/PSS), polyaniline, polyacetylene, or polyphenylenevinylene.

The second electrode pattern formed in the area other than the intersecting area may be formed of indium-tin oxide.

According to a third preferred embodiment of the present invention, there is provided a touch panel, including: a first transparent substrate; a first electrode pattern formed on one surface of the first transparent substrate in a mesh pattern; a second transparent substrate; a second electrode pattern formed on one surface of the second transparent substrate and having an intersecting area facing the first electrode pattern formed in the mesh pattern and an area other than the intersecting area formed in a surface type; and an adhesive layer bonding one surface of the first transparent surface to one surface of the second transparent substrate.

The touch panel may further include: an image display device formed in the other surface direction of the second transparent substrate.

At least one of the first electrode pattern and the second electrode pattern formed in the intersecting area may be formed of any one selected from copper (Cu), aluminum (Al), gold (Au), silver (Ag), titanium (Ti), palladium (Pd), and chromium (Cr), or a combination thereof.

At least one of the first electrode pattern and the second electrode pattern formed in the intersecting area may be formed of metal silver formed by exposing/developing a silver salt emulsion layer.

The second electrode pattern formed in the area other than the intersecting area may be formed of poly-3,4-ethylenedioxythiophene/polystyrenesulfonate (PEDOT/PSS), polyaniline, polyacetylene, or polyphenylenevinylene.

The second electrode pattern formed in the area other than the intersecting area may be to formed of indium-tin oxide.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exploded perspective view of a touch panel according to a first preferred embodiment of the present invention;

FIGS. 2A and 2B are cross sectional views of the touch panel shown in FIG. 1;

FIG. 3 is an exploded perspective view of a touch panel according to a second preferred embodiment of the present invention;

FIGS. 4A and 4B are cross sectional views of the touch panel shown in FIG. 3;

FIG. 5 is an exploded perspective view of a touch panel according to a third preferred embodiment of the present invention; and

FIGS. 6A and 6B are cross sectional views of the touch panel shown in FIG. 5.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

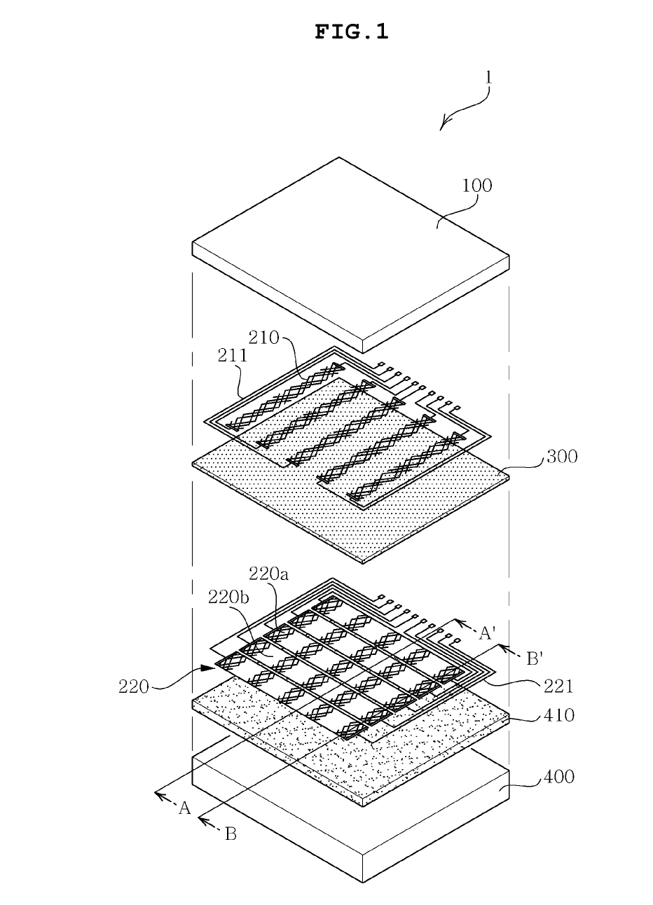

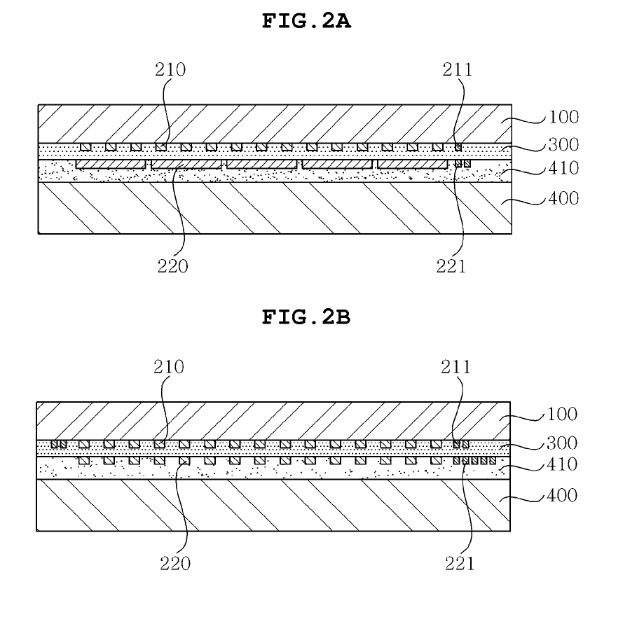

FIG. 1 is an exploded perspective view of a touch panel according to a lint preferred embodiment of the present invention, FIG. 2A is a cross sectional view of the line A-A′ shown in FIG. 1, and FIG. 2B is a cross-sectional view of the B-B′ shown in FIG. 1.

As shown in FIGS. 1 and 2, a touch panel 1 according to a preferred embodiment of the present invention includes a transparent substrate 100, a first electrode pattern 210 formed on the transparent substrate 100 in a mesh pattern, an insulating layer 300 formed on the transparent substrate 100, and a second electrode pattern 220 formed on an exposed surface of the insulating layer 300 and having an intersecting area 220a facing the first electrode pattern 210 formed in the mesh pattern and an area 220b other than the intersecting area formed in a surface type.

The transparent substrate 100 provides an area in which the first electrode pattern 210 is formed. Here, the transparent substrate 100 needs to have support force capable of supporting the first electrode pattern 210 and transparency to allow a user to recognize images provided from an image display device 400.

In consideration of the support force and the transparency described above, the transparent substrates 110 may be formed of polyethylene terephthalate (PET), polycarbonate (PC), poly methyl methacrylate (PMMA), polyethylene naphthalate (PEN), polyethersulpon (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), glass, or tempered glass, but are not necessarily limited thereto.

One surface of the transparent substrate 100 is preferably activated by being subjected to high frequency treatment or primer treatment. The transparent substrate 100 is treated as described above, thereby more improving adhesion between the transparent substrate 100 and the first electrode pattern 210.

Meanwhile, the transparent substrate 100 may be a window that is provided at an outermost side of the touch panel. When the transparent substrate 100 is the window, the first electrode pattern 210 is directly formed on the window. Further, the present structure may be formed of a G2 structure in which the first electrode pattern 210 and the second electrode pattern 220, having the insulating layer 300 formed therebetween, are formed on one surface of the window by forming the insulating layer 300 on which the second electrode pattern 220 to be described below is formed on one surface of the window. In this case, a process of manufacturing a touch panel may omit a process of forming electrodes on a separate transparent substrate and then, bonding the formed electrodes to the window, such that the overall thickness of the touch panel can be reduced.

The insulating layer 300 serves to provide an area in which the second electrode pattern 220 is formed, while protecting the first electrode pattern 210. The insulating layer 300 is formed on one surface of the transparent substrate 100 so as to cover the first electrode pattern 210. Here, the insulating layer 300 may be formed of epoxy, acrylic-based resin, a SiOx thin film, a SiNx thin film, and the like. Further, the insulating layer 300 may be formed by methods, such as printing, chemical vapor deposition (CVD), sputtering, and the like.

The first electrode pattern 210 and the second electrode pattern 220 serve to allow a user to recognize touched coordinates in a controller (not shown) by generating signals when they are touched by a user.

The first electrode pattern 210 is formed on one surface of the transparent substrate 100 in a mesh pattern. The first electrode pattern 210 may be formed of any one selected from copper (Cu), aluminum (Al), gold (Au), silver (Ag), titanium (Ti), palladium (Pd), and chromium (Cr), or a combination thereof. In this case, the first electrode pattern 210 may be formed by a plating process or an evaporation process. Meanwhile, when the first electrode pattern 210 is formed of copper (Cu), a surface of the first electrode pattern 210 may be preferably subjected to a black oxide treatment. Here, a process of precipitating Cu₂O or CuO by oxidizing the surface of the first electrode pattern 210 is referred to as black oxide treatment, wherein the Cu₂O has blown and is thus referred to as blown oxide and the CuO has black and is thus referred to as black oxide. As described above, the first electrode pattern 210 is subjected to the black oxide treatment to prevent light reflection, thereby improving visibility of the touch panel. The first electrode pattern 210 may be formed of metal silver formed by exposing/developing a silver salt emulsion layer, in addition to the foregoing metals.

The second electrode pattern 220 is formed on the exposed surface of the insulating layer 300.

In the overall area of the second electrode pattern 220, the intersecting area 220a vertically facing the first electrode pattern 210 through the insulating layer 300 is formed in the mesh pattern as shown in FIGS. 1 and 2B. The mesh pattern formed in the intersecting area 220a may be formed of any one selected from copper (Cu), aluminum (Al), gold (Au), silver (Ag), titanium (Ti), palladium (Pd), and chromium (Cr), or a combination thereof. Further, the mesh pattern formed in the intersecting area 220a may be formed by the plating process or the evaporation process, similar to the first electrode pattern 210. The mesh pattern formed in the intersecting area 220a may be formed of the metal silver formed by exposing/developing the silver salt emulsion layer, in addition to the foregoing metals.

Meanwhile, the intersecting area 220a of the second electrode pattern is formed in the mesh pattern of metals as described above and thus, capacitance generated between the first electrode pattern 210 and the second electrode pattern 220 is not excessively large. As a result, the touch panel 1 according to the preferred embodiment of the present invention can secure the sufficient touch strength while minimizing the thickness of the insulating layer 300, which will be below in more detail with reference to the following Table.

| | ITO Surface Electrode | | | Metal Mesh Electrode | | |
|---|---|---|---|---|---|---|
| | Capacitance(C)[pF] | | Touch | Capacitance (C)[pF] | | Touch |
| Gap | Before | After | Strength | Before | After | Strength |
| [um] | Touch | Touch | (ΔC)[%] | Touch | Touch | (ΔC)[%] |
| 278 | 0.880 | 0.699 | 20.5 | 0.639 | 0.468 | 26.8 |
| 225 | 1.038 | 0.848 | 18.3 | 0.712 | 0.541 | 24.0 |
| 180 | 1.242 | 1.054 | 15.1 | 0.801 | 0.629 | 21.5 |
| 130 | 1.665 | 1.477 | 11.3 | 0.953 | 0.781 | 18.0 |
| 80 | 2.317 | 2.135 | 7.9 | 1.132 | 0.967 | 14.6 |
| 30 | 4.511 | 4.304 | 4.6 | 1.556 | 1.394 | 10.4 |
| 10 | 12.205 | 12.027 | 1.5 | 2.664 | 2.509 | 5.8 |

<Experimental Data of Capacitance C and Touch Strength ΔC According to Gap Between Upper and Lower Electrodes>

The table shows the experimental results obtained by confirming a change in capacitance C and touch intensity ΔC between a first electrode and a second electrode vertically facing each other according to a thickness of a member such as the insulating layer 300, that is, a gap between the first electrode and the second electrode vertically facing each other, in the touch panel including a structure in which the first electrode and the second electrode are formed on both surface of the member, such as the insulating layer 300, and the like, according to the preferred embodiment of the present invention.

Here, the touch strength ΔC shows the variation of capacitance between the first electrode and the second electrode in a unit of percentage % that is generated before and after being touched by the user or other input units. Generally, when the touch strength is 10% or more, good touch sensitivity and touch strength can be secured.

First, when reviewing the experimental results of the ‘ITO surface electrode’ shown in the above Table, the present experimental results correspond to the experimental results of the touch panel having the surface electrode structure in which both of the first electrode and the second electrode are formed of indium-thin oxide (ITO). As can be appreciated from the experimental data, when the gap between the electrodes is 100 μm or more, it can be appreciated that the touch strength ΔC of 10 or more is obtained. That is, the member such as the insulating layer 300 according to the preferred embodiment of the present invention forming the gap between the upper and lower electrodes needs to be formed to have the thickness of 100 μm or more, thereby obtaining the desired touch sensitivity.

Next, reviewing the experimental results of the ‘metal mesh electrode’ shown in the above Table, the present experimental results correspond to the experimental results of the touch panel in which both of the first electrode and the second electrode are formed as the mesh type electrode of metals. As can be appreciated from the experimental data, when the gap between the electrodes is 30 μm or more, it can be appreciated that the touch strength of 10% or more can be secured in advance. That is, even when the member such as the insulating layer 300 according to the preferred embodiment of the present invention forming the gap between the upper and lower electrodes is manufactured in a thin type, the desired touch sensitivity can be acquired.

According to the present experimental results, when an absolute value of capacitance variation shown after and before being touched in the case of the ‘ITO surface electrode’ and in the case of the ‘metal mesh electrode’ in the state of the same gap compares with each other, even though the difference in the absolute values is not large, the capacitance value of the state before being touched is much more generated in the case of the ‘ITO surface electrode’ than in the case of the ‘metal mesh electrode’. Therefore, it can be appreciated that the case of the ‘ITO surface electrode’ has much lower touch strength in the same gap in the case of the ‘ITO surface electrode’ than in the case of the ‘metal mesh electrode’.

As described above, in the touch panel 1 according to the preferred embodiment of the present invention, the first electrode pattern 210 is formed in the mesh pattern of metal and the intersecting area of the second electrode pattern 220 is similarly formed in the mesh pattern of metal, which correspond to the case in which the upper and lower electrodes are formed as the ‘metal mesh electrode’ in the above experimental example. Therefore, the touch panel 1 according to the preferred embodiment of the present invention can obtain the desired touch sensitivity even though the thickness of the insulating layer 300 is very thinly manufactured, as compared with the touch panel structure in which the upper and lower electrodes are formed as the ITO surface electrode, thereby making it possible to realize the thinness of the touch panel structure.

Meanwhile, in the overall area of the second electrode pattern 220, the remaining area 220b other than the foregoing intersecting area is formed in a surface type as shown in FIGS. 1 and 2A. The second electrode pattern 220 formed in the surface type in the area 220b may be formed of conductive polymer or metal oxide. Here, the conductive polymer has excellent flexibility and a simple coating process. In this case, the conductive polymer may be formed of poly-3,4-ethylenedioxythiophene/polystyrenesulfonate (PEDOT/PSS), polyaniline, polyacetylene, or polyphenylenevinylene. In addition, the metal oxide may be formed of indium-tin oxide. Further, the second electrode pattern 220 formed in the surface type in the area 220b may be formed by a dry process, a wet process, and a direct patterning process. Here, the dry process means sputtering, evaporation, and the like, the wet process means dip coating, spin coating, roll coating, spray coating, and the like, and the direct patterning process means screen printing, gravure printing, inkjet printing, and the like.

Meanwhile, the electrode pattern is formed in the mesh pattern, thereby lowering surface resistance. However, an aperture portion is present between the mesh patterns and therefore, it may be difficult to shield noises occurring from an image display device 400. However, in the overall area of the second electrode pattern 220, the area 220b other than the foregoing intersecting area 220a is formed in the surface type and therefore, it is possible to effectively shield the noises occurring from the image display device 400 and thus, prevent the occurrence of electro magnetic interference (EMI).

The first electrode pattern 210 and the second electrode pattern 220 are formed in a bar type pattern in the drawings, but are not limited thereto. The first electrode pattern 210 and the second electrode pattern 220 may be formed in all the patterns known to those skilled in the art, such as a diamond pattern, a quadrangular pattern, a triangular pattern, a circular pattern, and the like.

The touch panel 1 according to the preferred embodiment of the present invention may further include the image display device 400. The image display device 400 serves to output an image. The image display device 400 is formed in an exposed surface direction of the insulating layer 300. The image display device 400 includes a liquid crystal display (LCD) device, a plasma display panel (PDP), electroluminescence (EL), a cathode ray tube (CRT), and the like. In addition, the image display device 400 may be bonded to the exposed surface of the insulating layer 300 by an adhesive means such as an optical clear adhesive (OCA) 410, and the like. Meanwhile, even though noises occur in the image display device 400, as described above, the noises are effectively shielded by the second electrode pattern 220 formed in the area 220b other than the intersecting area 220a in the surface type, such that the touch panel 1 according to the preferred embodiment of the present invention can prevent the occurrence of the EMI.

In addition, an edge of the first electrode pattern 210 may be provided with a first electrode wiring 211 that receives electrical signals from the first electrode pattern 210. In addition, an edge of the second electrode pattern 220 may be provided with a second electrode wiring 221 that receives electrical signals from the second electrode pattern 220. In this case, the first electrode wiring 211 is integrally formed with the first electrode pattern 210 and the second electrode wiring 221 is integrally formed with the second electrode pattern 220, thereby making it possible to simplify the manufacturing process and shorten lead time.

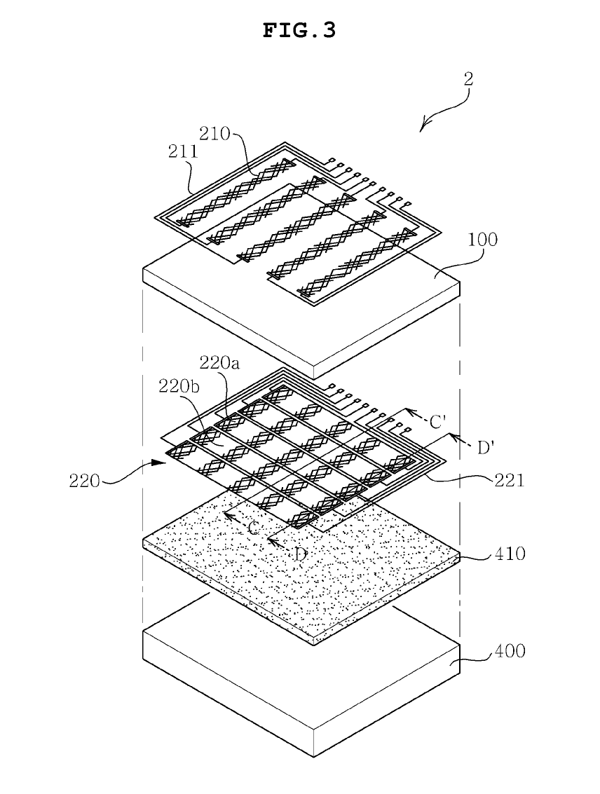

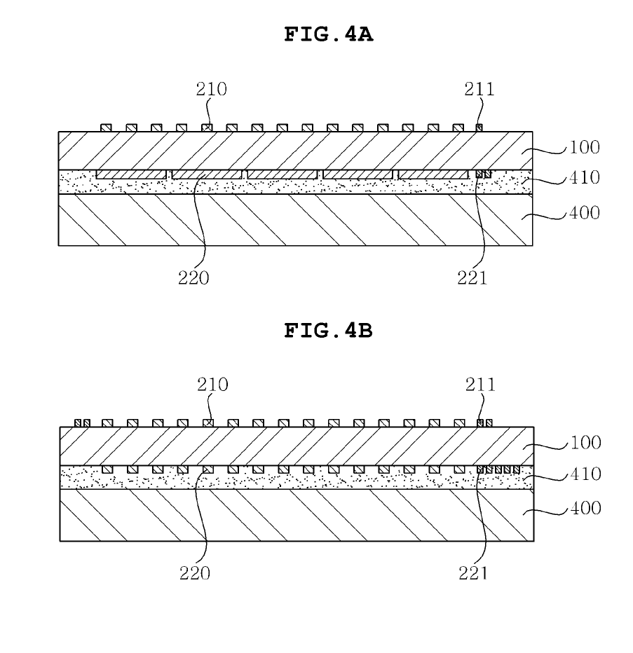

FIG. 3 is an exploded perspective view of a touch panel according to a second preferred embodiment of the present invention, FIG. 4A is a cross sectional view of the line C-C′ shown in FIG. 3, and FIG. 4B is a cross-sectional view of the D-D′ shown in FIG. 3.

As shown in FIGS. 3 and 4, a touch panel 2 according to a preferred embodiment of the present invention includes the transparent substrate 100, the first electrode pattern 210 formed on one surface of the transparent substrate 100 in the mesh pattern, and the second electrode pattern 220 formed on the other surface of the transparent substrate 100 and having the intersecting area 220a facing the first electrode pattern 210 in the mesh pattern and the area 220b other than the intersecting area formed in the surface type.

When the touch panel 2 according to the preferred embodiment of the present invention compares with the touch panel 1 according to the first embodiment as described above, they have a difference in that the second electrode pattern 220 is formed on the other surface of the transparent substrate 100. Therefore, the overlapping contents with the description of the first preferred embodiment of the present invention are omitted below and a portion having a difference from the first preferred embodiment of the present invention will be mainly described.

The transparent substrate 100 provides an area in which the first and second electrode patterns 210 and 220 are formed. In this case, one surface and the other surface of the transparent substrate 100 may be activated by being subjected to the high frequency treatment or the primer treatment.

The first electrode pattern 210 is formed on one surface of the transparent substrate 100 in the mesh pattern and the second electrode pattern 220 is formed on the other surface of the transparent substrate 100. In this case, in the overall area of the second electrode pattern 220, the intersecting area 220a vertically facing the first electrode pattern 210 through the transparent to substrate 100 is formed in the mesh pattern as shown in FIGS. 3 and 4. In the overall area of the second electrode pattern 220, the remaining area 220b other than the foregoing intersecting area is formed in the surface type as shown in FIGS. 3 and 4A. The detailed function and material of the first and second electrode patterns 220 and the method for forming the same will be replaced with the description of the first and second electrode patterns 220 according to the first preferred embodiment of the present invention.

Similarly to the touch panel 1 according to the first embodiment of the present invention, in the touch panel 2 according to the preferred embodiment of the present invention, the intersecting area 220a of the second electrode pattern 220 may be formed in the mesh pattern of metal like the first electrode pattern 210. In this case, the touch panel 2 according to the preferred embodiment of the present invention may provide an advantage that the thickness of the transparent substrate 100 is thinly manufactured like the description of the foregoing experimental data.

In addition, the touch panel 2 according to the preferred embodiment of the present invention may further include the image display device 400, similar to the first preferred embodiment of the present invention. The image display device 400 is formed in the other surface direction of the insulating layer 100. The image display device 400 may be bonded to the other surface of the transparent substrate 100 by an optical clear adhesive 410. Further, the touch panel 2 according to the preferred embodiment of the present invention can effectively shield noises occurring from the image display device 400 by the second electrode pattern 220 formed in the surface type, similar to the first preferred embodiment of the present invention.

In the preferred embodiment of the present invention, the first electrode pattern 210 and the second electrode pattern 220 are formed in a bar type pattern in the drawings, but are not limited thereto. Similar to the first preferred embodiment of the present invention, the first electrode pattern 210 and the second electrode pattern 220 may be formed in all the patterns known to those skilled in the art, such as a diamond pattern, a quadrangular pattern, a triangular pattern, a circular pattern, and the like. In addition, in the preferred embodiment of the present invention, similar to the first preferred embodiment of the present invention, the edge of the first electrode pattern 210 ma be provided with the first electrode wiring 211 and the edge of the second electrode pattern 220 may be provided with the second electrode wiring 221.

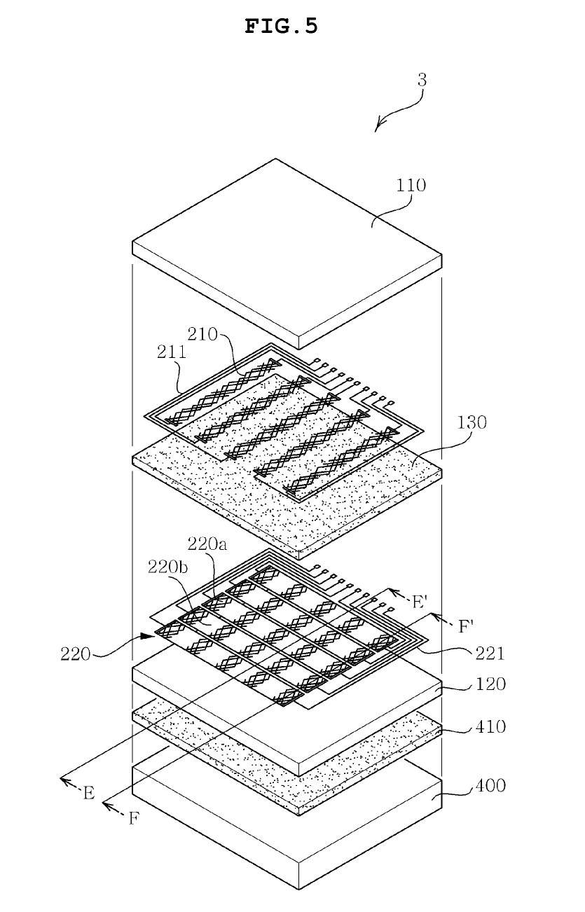

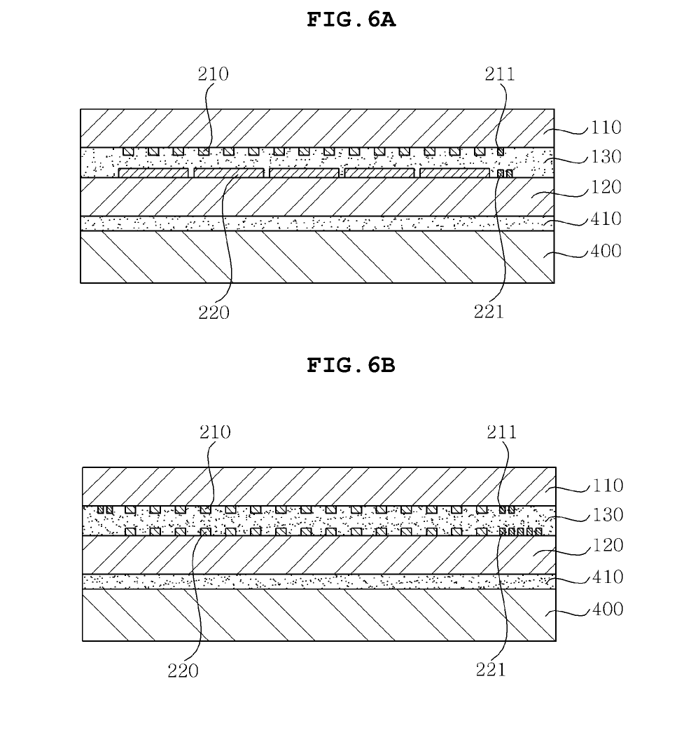

FIG. 5 is an exploded perspective view of a touch panel according to a third preferred embodiment of the present invention, FIG. 6A is a cross sectional view of the line E-E′ shown in FIG. 5, and FIG. 6B is a cross-sectional view of the F-F′ shown in FIG. 5.

As shown in FIGS. 5 and 6, a touch panel 3 according to the preferred embodiment of the present invention includes the first transparent substrate 110, the first electrode pattern 210 formed on one surface of the first transparent substrate 110 in the mesh pattern, the second transparent substrate 120, the second electrode pattern 220 formed on one surface of the second transparent substrate 120 and having the intersecting area 220a facing the first electrode pattern 210 formed in the mesh pattern and the area 220b other than the intersecting area formed in a surface type, and the adhesive layer 130 bonding one surface of the first transparent surface 110 to one surface of the second transparent substrate 120.

When comparing the touch panel 3 according to the preferred embodiment of the present invention with the touch panel 1 according to the first preferred embodiment of the present invention, they have a difference in that the first electrode pattern 210 is formed on one surface of the first transparent substrate 110, the second electrode pattern 220 is formed on one surface of the second transparent substrate 120, and the first transparent substrate 110 and the second transparent substrate 120 are bonded to each other by the adhesive layer 130. Therefore, the overlapping contents with the description of the first preferred embodiment of the present invention are omitted below and a portion having a difference from the first preferred embodiment of the present invention will be mainly described.

The first and second transparent substrates 110 and 120 serve to provide the area in which the first and second electrode patterns 210 and 220 are formed. In this case, one surface of the first and second transparent substrates 110 and 120 may each be activated by being subjected to the high frequency treatment or the primer treatment. The detailed material of the first and second transparent substrates 110 and 120 will be replaced with the description of the transparent substrate 100 according to the first preferred embodiment of the present invention. However, in this case, the first transparent substrate 100 may be the window provided at the outermost side of the touch panel. In this case, the first electrode pattern 210 is directly formed on the window and therefore, the process of manufacturing the touch panel may omit the process of forming the first electrode pattern on the separate transparent substrate and then, bonding the formed first electrode pattern to the window. Further, the overall thickness of the touch panel may be reduced.

The first electrode pattern 210 is formed on one surface of the transparent substrate 100 in the mesh pattern and the second electrode pattern 220 is formed on one surface of the second transparent substrate 120. In this case, in the overall area of the second electrode pattern 220, the intersecting area 220a vertically facing the first electrode pattern 210 through the adhesive layer 130 is formed in the mesh pattern as shown in FIGS. 5 and 6. In the overall area of the second electrode pattern 220, the remaining area 220b other than the foregoing intersecting area is formed in the surface type as shown in FIGS. 5 and 6A. The detailed function and material of the first and second electrode patterns 220 and the method for forming the same will be replaced with the description of the first and second electrode patterns 210,220 according to the first preferred embodiment of the present invention.

The adhesive layer 130 serves to bond one surface of the first transparent substrate 110 to one surface of the second transparent substrate 120. The adhesive layer 130 is not particularly limited, but may use the optical clear adhesive.

Like the foregoing first and second preferred embodiments of the present invention, in the touch panel 3 according to the preferred embodiment of the present invention, the intersecting area 220a of the second electrode pattern 220 may be formed in the mesh pattern of metal like the first electrode pattern 210. In this case, the thickness of the adhesive layer 130 can be thinly manufactured.

In addition, the touch panel 3 according to the preferred embodiment of the present invention may further include the image display device 400, similar to the first preferred embodiment of the present invention. The image display device 400 is formed in the other surface direction of the second transparent substrate 120. The image display device 400 may be bonded to the other surface of the transparent substrate 100 by an optical clear adhesive 410. Further, the touch panel 3 according to the preferred embodiment of the present invention can effectively shield noises occurring from the image display device 400 by the second electrode pattern 220 formed in the surface type, similar to the first preferred embodiment of the present invention.

In the preferred embodiment of the present invention, the first electrode pattern 210 and the second electrode pattern 220 are formed in a bar type pattern in the drawings, but are not limited thereto. Similar to the first preferred embodiment of the present invention, the first electrode pattern 210 and the second electrode pattern 220 may be formed in all the patterns known to those skilled in the art, such as a diamond pattern, a quadrangular pattern, a triangular pattern, a circular pattern, and the like. In addition, in the preferred embodiment of the present invention, similar to the first preferred embodiment of the present invention, the edge of the first electrode pattern 210 ma be provided with the first electrode wiring 211 and the edge of the second electrode pattern 220 may be provided with the second electrode wiring 221.

According to the preferred embodiments of the present invention, the area of the second electrode pattern facing the first electrode pattern is formed in the mesh pattern of metals similar to the first electrode pattern, thereby making it possible to sufficiently use the low resistance characteristics of metals. Further, even though the thickness of the transparent substrate, the insulating layer, or the adhesive layer disposed between the first electrode pattern and the second electrode pattern is thin, the excessively large capacitance does not occur. Therefore, it is possible to secure the desired touch sensitivity while thinly forming the thickness of the transparent substrate, the insulating layer, or the adhesive layer. In particular, it is possible to solve the problem in that the thickness of the insulating layer is thickly formed in the touch panel structure such as, for example, the G2 structure in which the electrode patterns are directly formed on the window and implement the thinness of the touch panel structure.

Moreover, according to the preferred embodiments of the present invention, it is possible to effectively shield noises occurring from the image display device by forming the second electrode pattern not facing the first electrode pattern in a surface type.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel, comprising:
a transparent substrate;
a first electrode pattern formed on the transparent substrate in a mesh pattern;
an insulating layer formed on the transparent substrate; and
a second electrode pattern formed on an exposed surface of the insulating layer and having an intersecting area facing the first electrode pattern formed in a mesh pattern and an area other than the intersecting area formed in a surface type.

2. The touch panel as set forth in claim 1, further comprising: an image display device formed in an exposed surface direction of the insulating layer.

3. The touch panel as set forth in claim 1, wherein at least one of the first electrode pattern and the second electrode pattern formed in the intersecting area is formed of any one selected from copper (Cu), aluminum (Al), gold (Au), silver (Ag), titanium (Ti), palladium (Pd), and chromium (Cr), or a combination thereof.

4. The touch panel as set forth in claim 1, wherein at least one of the first electrode pattern and the second electrode pattern formed in the intersecting area is formed of metal silver formed by exposing/developing a silver salt emulsion layer.

5. The touch panel as set forth in claim 1, wherein the second electrode pattern formed in the area other than the intersecting area is formed of poly-3,4-ethylenedioxythiophene/polystyrenesulfonate (PEDOT/PSS), polyaniline, polyacetylene, or polyphenylenevinylene.

6. The touch panel as set forth in claim 1, wherein the second electrode pattern formed in the area other than the intersecting area is formed of indium-tin oxide.

7. A touch panel, comprising:
a transparent substrate;
a first electrode pattern formed on one surface of the transparent substrate in a mesh pattern; and
a second electrode pattern formed on the other surface of the transparent substrate and having an intersecting area facing the first electrode pattern formed in the mesh pattern and an area other than the intersecting area formed in a surface type.

8. The touch panel as set forth in claim 7, further comprising: an image display device formed in the other surface direction of the transparent substrate.

9. The touch panel as set forth in claim 7, wherein at least one of the first electrode pattern and the second electrode pattern formed in the intersecting area is formed of any one selected from copper (Cu), aluminum (Al), gold (Au), silver (Ag), titanium (Ti), palladium (Pd), and chromium (Cr), or a combination thereof.

10. The touch panel as set forth in claim 7, wherein at least one of the first electrode pattern and the second electrode pattern formed in the intersecting area is formed of metal silver formed by exposing/developing a silver salt emulsion layer.

11. The touch panel as set forth in claim 7, wherein the second electrode pattern formed in the area other than the intersecting area is formed of poly-3,4-ethylenedioxythiophene/polystyrenesulfonate (PEDOT/PSS), polyaniline, polyacetylene, or polyphenylenevinylene.

12. The touch panel as set forth in claim 7, wherein the second electrode pattern formed in the area other than the intersecting area is formed of indium-tin oxide.

13. A touch panel, comprising:
a first transparent substrate;
a first electrode pattern formed on one surface of the first transparent substrate in a mesh pattern;
a second transparent substrate;
a second electrode pattern formed on one surface of the second transparent substrate and having an intersecting area facing the first electrode pattern formed in the mesh pattern and an area other than the intersecting area formed in a surface type; and
an adhesive layer bonding one surface of the first transparent surface to one surface of the second transparent substrate.

14. The touch panel as set forth in claim 13, further comprising: an image display device formed in the other surface direction of the second transparent substrate.

15. The touch panel as set forth in claim 13, wherein at least one of the first electrode pattern and the second electrode pattern formed in the intersecting area is formed of any one selected from copper (Cu), aluminum (Al), gold (Au), silver (Ag), titanium (Ti), palladium (Pd), and chromium (Cr), or a combination thereof.

16. The touch panel as set forth in claim 13, wherein at least one of the first electrode pattern and the second electrode pattern formed in the intersecting area is formed of metal silver formed by exposing/developing a silver salt emulsion layer.

17. The touch panel as set forth in claim 13, wherein the second electrode pattern formed in the area other than the intersecting area is formed of poly-3,4-ethylenedioxythiophene/polystyrenesulfonate (PEDOT/PSS), polyaniline, polyacetylene, or polyphenylenevinylene.

18. The touch panel as set forth in claim 13, wherein the second electrode pattern formed in the area other than the intersecting area is formed of indium-tin oxide.
